(19) United States
(12) Patent Application Publication
(10) Pub. No.: US 2018/0190928 A1
(43) Pub. Date: Jul. 5, 2018

(54) Organic Light-Emitting Diode, Display Panel and Display Device

(71) Applicant: Shanghai Tianma AM-OLED Co., Ltd., Shanghai (CN)

(72) Inventors: Xiangcheng Wang, Shanghai (CN); Jinghua Niu, Shanghai (CN)

(21) Appl. No.: 15/910,890

(22) Filed: Mar. 2, 2018

(30) Foreign Application Priority Data
Aug. 1, 2017 (CN) 201710648482.5

(51) Int. Cl. H01L 51/50; H01L 51/52; G09G 3/3258

(52) U.S. Cl. CPC H01L 51/5056; H01L 51/5206; G09G 3/3258; H01L 51/5072; H01L 51/5221

(57) ABSTRACT

The disclosure discloses an organic light-emitting diode, a display panel and a display device, where organic light-emitting diode includes an anode, a cathode, at least two light emitting layers arranged between the anode and the cathode, and a hole transport element and an electron transport element which are arranged between two adjacent light emitting layers. Where both the hole transport element and the electron transport element include at least two transport layers, and the volume concentration of the P-type material of the hole transport layer adjacent to the electron transport element is higher, and the volume concentration of the N-type material of the electron transport layer adjacent to the hole transport element is higher.

This application claims the benefit of Chinese Patent Application No. CN 201710648482.5, filed with the Chinese Patent Office on Aug. 1, 2017, which is hereby incorporated by reference in its entirety.

### FIELD

The present disclosure relates to the technical field of display, and particularly to an organic light-emitting diode, a display panel and a display device.

### BACKGROUND

The organic electroluminescence is a phenomenon in which organic materials are excited by an electric energy for light emitting. With the advantages of low drive voltage, high luminous brightness, high luminous efficiency, wide luminous viewing angle, high response speed, ultrathin shape, light weight and compatible flexible substrate, the organic light-emitting devices occupy an important position in the field of display.

As a representative product of organic electroluminescent devices, the organic light-emitting diode (OLED) has been extensively studied.

Please refer to FIG. 1. The structure of the organic light-emitting diode in the related art includes a cathode 0100, an electron injection layer 01, an electron transport layer 02, a first light emitting layer 031, a spaced layer 04, a second light emitting layer 032, a hole transport layer 05, a hole injection layer 06 and an anode 0200 which are arranged in sequence in an overlaying manner. In the organic light-emitting diode with such a structure, the carrier mobility of the first light emitting layer 031 and the second light emitting layer 032 of the light emitting layer 03 is relatively poor, thereby resulting in a lower injection efficiency of the electrons and holes, thus resulting in a lower luminous efficiency of the organic light-emitting diode. In addition, along with the change of the drive voltage, the quantity of the electrons and holes injecting into the first light emitting layer 031 and the second light emitting layer 032 also changes, thereby resulting in the movement of a luminescent recombination center, thus resulting in an unstable luminous color and a poorer luminous effect.

In the related art, in order to solve the above problems, a charge generating layer can be arranged between the first light emitting layer and the second light emitting layer to solve the above technical problem that the luminous color is unstable and the luminous effect is poorer. However, the setting of the charge generating layer will also result in a problem of rising of the drive voltage of the organic light-emitting diode and decreasing of the luminous efficiency.

### SUMMARY

An organic light-emitting diode provided by an embodiment of the present disclosure includes an anode, a cathode, at least two light emitting layers arranged between the anode and the cathode, and a hole transport element and an electron transport element which are arranged between every two adjacent light emitting layers and arranged in sequence along a direction far away from the cathode. Where the hole transport element includes at least two hole transport layers, where each of the hole transport layers includes a hole transport material and a P-type material doped in the hole transport material, and in the at least two hole transport layers, a volume concentration of the P-type material of a hole transport layer adjacent to the light emitting layer is less than a volume concentration of the P-type material of a hole transport layer adjacent to the electron transport element. The electron transport element includes at least two electron transport layers, where each of the electron transport layer includes an electron transport material and an N-type material doped in the electron transport material, and in the at least two electron transport layers, a volume concentration of the N-type material of an electron transport layer adjacent to the light emitting layer is less than a volume concentration of the N-type material of an electron transport layer adjacent to the hole transport element.

The embodiments of the present disclosure further provide a display panel, and the display panel includes the organic light-emitting diode of any one of the above technical solutions.

In the present embodiments, the drive voltage of the organic light-emitting diode is lower, then the power consumption is lower, the luminous efficiency is higher, and the service life is prolonged.

The embodiments of the present disclosure further provide a display device, and the display device includes the display panel in the above solution.

### BRIEF DESCRIPTION OF THE DRAWINGS

FIG. 1 is a structural schematic diagram of an organic light-emitting diode in an embodiment of the related art.

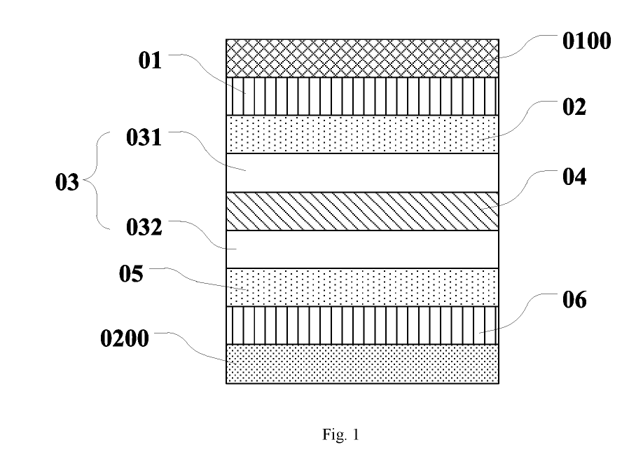

FIG. 2 is a structural schematic diagram of an organic light-emitting diode in a first embodiment of the present disclosure.

FIG. 3 is a structural schematic diagram of an organic light-emitting diode in a second embodiment of the present disclosure.

FIG. 4 is a structural schematic diagram of an organic light-emitting diode in another embodiment of the related art.

FIG. 5 is a structural schematic diagram of an organic light-emitting diode in a third embodiment of the present disclosure.

FIG. 6 is a structural schematic diagram of an organic light-emitting diode in a fourth embodiment of the present disclosure.

FIG. 7 is a structural schematic diagram of an organic light-emitting diode in a fifth embodiment of the present disclosure.

FIG. 8 is a structural schematic diagram of a display device in an embodiment of the present disclosure.

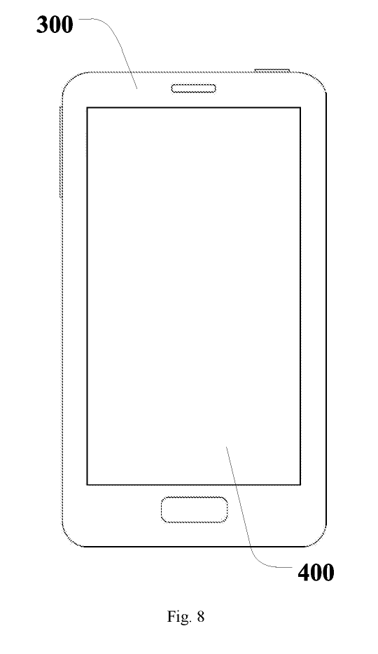

### DETAILED DESCRIPTION OF THE EMBODIMENTS

In order to lower the drive voltage of the organic light-emitting diode, improve the luminous efficiency and prolong the service life of the organic light-emitting diode, the embodiments of the present disclosure provide an organic light-emitting diode, a display panel and a display device. In order to make the objective, technical solution and advantages of the present disclosure clearer, the present disclosure will be further described in detail below with the embodiments as examples.

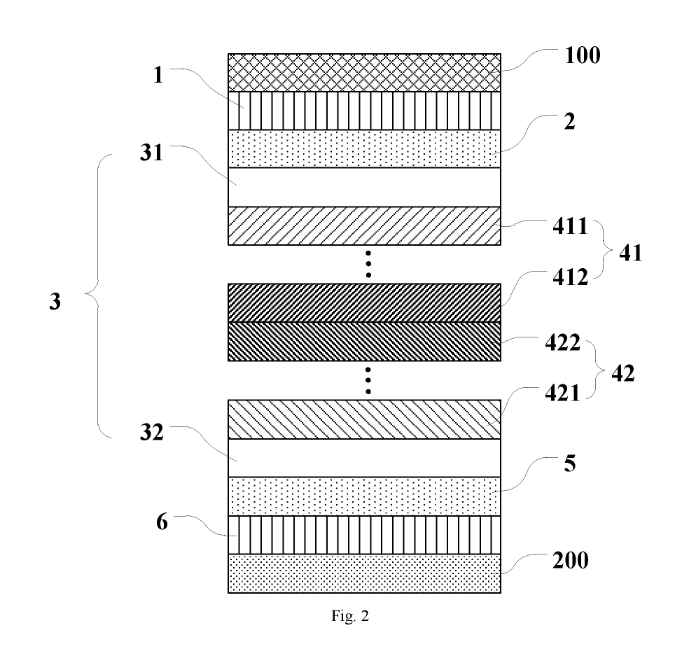

As shown in FIG. 2, the organic light-emitting diode provided by a first embodiment of the present disclosure includes an anode 200, a cathode 100, at least two light emitting layers 3 arranged between the anode 200 and the cathode 100, and a hole transport element 41 and an electron transport element 42 which are arranged between every two adjacent light emitting layers 3 and arranged in sequence along the direction far away from the cathode 100.

Where the hole transport element 41 includes at least two hole transport layers, where each of the hole transport layers includes a hole transport material and a P-type material doped in the hole transport material, and in the at least two hole transport layers, the volume concentration of the P-type material of the hole transport layer 411 adjacent to the light emitting layer 3 is less than the volume concentration of the P-type material of the hole transport layer 412 adjacent to the electron transport element 42.

The electron transport element 42 includes at least two electron transport layers, where each of the electron transport layer includes an electron transport material and an N-type material doped in the electron transport material, and in the at least two electron transport layers, the volume concentration of the N-type material of the electron transport layer 421 adjacent to the light emitting layer 3 is less than the volume concentration of the N-type material of the electron transport layer 422 adjacent to the hole transport element 41.

As shown in FIG. 2, the organic light-emitting diode provided by the first embodiment of the present disclosure includes a cathode 100, an electron injection layer 1, an electron transport layer 2, a first light emitting layer 31, a hole transport element 41, an electron transport element 42, a second light emitting layer 32, a hole transport layer 5, a hole injection layer 6 and an anode 200 which are arranged in sequence. The hole transport element 41 and the electron transport element 42 are arranged between light emitting layers 3 and are configured to transport holes and electron respectively. In the present disclosure, the materials of the layer structures used for transporting holes between two light emitting layers 3 are the same, then the energy barrier between adjacent layer structures is smaller, and only a smaller drive voltage is required to inject the holes from one layer structure to the adjacent layer structure. Similarly, the materials of the layer structures for transporting electrons between light emitting layers 3 are also the same, the drive voltage required for electron injection is also smaller, therefore, and the solution can speed up the mobility of the holes and electrons, and lower the drive voltage of the organic light-emitting diode.

For the hole transport element 41, in the at least two hole transport layers, the volume concentration of the P-type material of the hole transport layer 411 adjacent to the light emitting layer 3 is less than the volume concentration of the P-type material of the hole transport layer 412 adjacent to the electron transport element 42, if the volume concentration of the P-type material of the hole transport layer 411 adjacent to the light emitting layer 3 is lower, then the P-type material is difficult to permeate into the light emitting layer 3, and it may also isolate the hole transport layer with a higher volume concentration of the P-type material from the light emitting layer 3, such that the P-type material with a higher volume concentration is also difficult to permeate into the light emitting layer 3, and the problem of luminescence quenching is not easily caused. Similarly, for the electron transport element 42, in the at least two electron transport layers, the volume concentration of the N-type material of the electron transport layer 421 adjacent to the light emitting layer 3 is less than the volume concentration of the N-type material of the electron transport layer 422 adjacent to the hole transport element 41, if the volume concentration of the N-type material of the electron transport layer adjacent to the light emitting layer 3 is lower, then the N-type material is difficult to permeate into the light emitting layer, and the problem of luminescence quenching is not easily caused. While the volume concentration of the P-type material of the hole transport layer 412 adjacent to the electron transport element 42 is higher, and the volume concentration of the N-type material of the electron transport layer 422 adjacent to the hole transport element 41 is higher, namely, the doping concentrations of the hole transport layer 412 and the electron transport layer 422 which are in contact with each other are higher, then the hole transport layer 412 and the electron transport layer 422 may produce more electrons and holes after being energized, such that the organic light-emitting diode is more easily to be turned on. Therefore, the solution can further lower the drive voltage of the organic light-emitting diode, and improve the luminous efficiency and prolong the service life of the organic light-emitting diode.

In one embodiment of the present disclosure, the volume concentrations of the P-type materials of the at least two hole transport layers increase in sequence along the direction far away from the cathode; and the volume concentrations of the N-type materials of the at least two electron transport layers increase in sequence along the direction far away from the anode.

In the embodiment of the present disclosure, the volume concentration of the P-type materials of the at least two hole transport layers changes gradually, thereby realizing gradient doping of the hole transport layer, forming a transport path to enable rapid transport of holes, and further speeding up the mobility of holes. Similarly, the layer structures for transporting electrons also adopt the design of the present solution, then a transport path to enable rapid transport of electrons is formed, and the mobility of electrons is sped up, therefore, the present solution can further lower the drive voltage of the organic light-emitting diode, improve the luminous efficiency and prolong the service life of the organic light-emitting diode.

In another embodiment, the thickness of the hole transport layer, adjacent to the light emitting layer, in the at least two hole transport layers is greater than the thickness of the remaining hole transport layers; and the thickness of the electron transport layer, adjacent to the light emitting layer, in the at least two electron transport layers is greater than the thickness of the remaining electron transport layers.

In the embodiment of the present disclosure, the thickness of the hole transport layer with a lower doping concentration of the P-type material and adjacent to the light emitting layer is larger, and the effect of isolating the hole transport layer with a higher volume concentration of the P-type material from the light emitting layer can be improved, such that it is difficult for the P-type material in the hole transport layer with a higher volume concentration of the P-type material to penetrate through the hole transport layer with a lower doping concentration of the P-type material and adjacent to the light emitting layer to thereby permeate into the light emitting layer, and the problem of luminescence quenching is not easily caused. Similarly, the thickness of the electron transport layer with a lower doping concentration of the N-type material and adjacent to the light emitting layer is larger, and the effect of isolating the electron transport layer with a higher volume concentration of the N-type material from the light emitting layer can be improved, such that it is difficult for the N-type material in the electron transport layer with a higher volume concentration of the N-type material to penetrate through the electron transport layer to thereby permeate into the light emitting layer, and the problem of luminescence quenching is not easily caused.

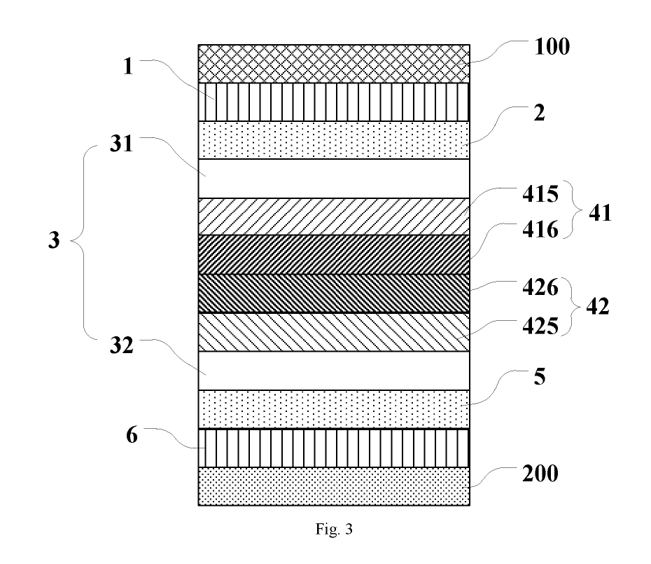

Please refer to FIG. 3. In a second embodiment of the present disclosure, the hole transport element 41 includes two hole transport layers, which are respectively the first hole transport layer 415 and the second hole transport layer 416 along the direction far away from the cathode 100. The electron transport element 42 includes two electron transport layers, which are respectively the first electron transport layer 425 and the second electron transport layer 426 along the direction far away from the anode 200.

In the embodiment, the hole transport element 41 and the electron transport element 42 respectively include two layer structures, and the structures thereof are simple and the manufacturing is convenient. The volume concentration of the P-type material of the first hole transport layer 415 is less than the volume concentration of the P-type material of the second hole transport layer 416, and the volume concentration of the N-type material of the first electron transport layer 425 is less than the volume concentration of the N-type material of the second electron transport layer 426. This solution solves the technical problem to be solved by the present disclosure with a simple structure, lowers the drive voltage of the organic light-emitting diode, and improves the luminous efficiency and prolongs the service life of the organic light-emitting diode.

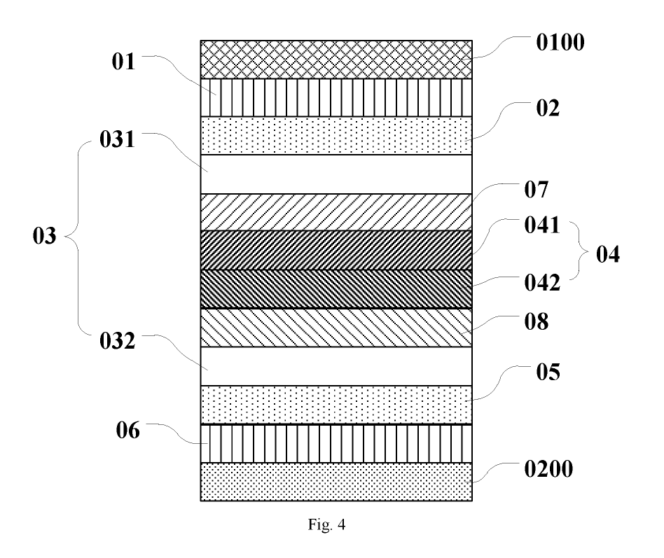

As shown in FIG. 4, the structure of an organic light-emitting diode in the related art is taken as a comparative example, the structure includes a cathode 0100, an electron injection layer 01, a fifth electron transport layer 02, a third light emitting layer 031, a sixth hole transport layer 07, a charge generating layer 04, a sixth electron transport layer 08, a fourth light emitting layer 032, a fifth hole transport layer 05, a hole injection layer 06 and an anode 0200 which are arranged in sequence in an overlaying manner. The charge generating layer 04 includes a P-type organic semiconductor layer 041 adjacent to the sixth hole transport layer 07 and an N-type organic semiconductor layer 042 adjacent to the sixth electron transport layer 08.

The related art shown in FIG. 4 has the following defects: the sixth hole transport layer 07, the P-type organic semiconductor layer 041, the N-type organic semiconductor layer 042 and the sixth electron transport layer 08 are arranged in sequence between two light emitting layers 03 along the direction far away from the cathode. Since the P-type organic semiconductor layer 041 of the charge generating layer 04 is adjacent to the sixth hole transport layer 07, the materials of the P-type organic semiconductor layer 041 and the sixth hole transport layer 07 are different, the energy level difference is larger, and it is difficult to transport the holes generated by the charge generating layer 04 to adjacent sixth hole transport layer 07. Similarly, since the N-type organic semiconductor layer 042 of the charge generation layer 04 is adjacent to the sixth electron transport layer 08, the materials of the N-type organic semiconductor layer 042 and the sixth electron transport layer 08 are different, and the energy level difference is larger; therefore, it is difficult to transport the electrons generated by the charge generating layer 04 to the adjacent sixth electron transport layer 08. In the comparative example, the drive voltage of the organic light-emitting diode rises, and the luminous efficiency is decreased.

Please refer to FIG. 3. In the second embodiment of the present disclosure, two light emitting layers 3 of the organic light-emitting diode include the first hole transport layer 415, the second hole transport layer 416, the first electron transport layer 425 and the second electron transport layer 426 which are arranged in sequence along the direction far away from the cathode, the materials of the layer structures used for transporting holes are the same, the energy level difference between the first hole transport layer 415 and the second hole transport layer 416 is small, thereby being beneficial for hole transport. Similarly, the energy level difference between the first electron transport layer 425 and the second electron transport layer 426 is small, thereby being beneficial for electron transport, so the required drive voltage is small, and the luminous efficiency is high.

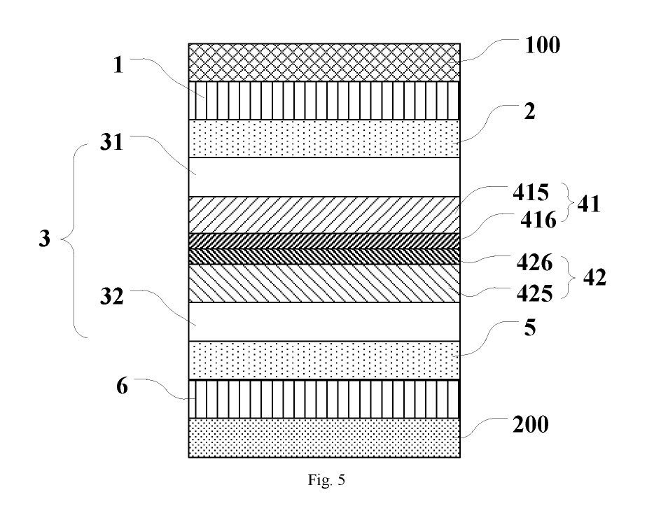

Please refer to FIG. 5. In a third embodiment of the present disclosure, the thickness of the first hole transport layer 415 is greater than the thickness of the second hole transport layer 416; and the thickness of the first electron transport layer 425 is greater than the thickness of the second electron transport layer 426.

In the present embodiment, the thickness of the first hole transport layer 415 is larger, and the effect of isolating the second hole transport layer 416 with a higher volume concentration of the P-type material from the light emitting layer can be improved, such that it is difficult for the P-type material in the second hole transport layer 416 with a higher volume concentration of the P-type material to penetrate through the first hole transport layer 415, and the problem of luminescence quenching is not easily caused. The setting for the thickness of the electron transport layer is the same as the above reasons, and will not be repeated redundantly herein.

In some embodiments, the thickness of the first hole transport layer 415 is 10 nm-120 nm, and within this thickness range, the effect of isolating the second hole transport layer 416 with a higher volume concentration of the P-type material from the light emitting layer by the first hole transport layer 415 is favorable. For example, the thickness of the first hole transport layer 415 may be 12 nm, 18 nm, 20 nm, 25 nm, 29 nm, 34 nm, 36 nm, 40 nm, 45 nm, 49 nm, 52 nm, 5 nm, 60 nm, 68 nm, 75 nm, 80 nm, 85 nm, 90 nm, 92 nm, 98 nm, 100 nm, 105 nm, 110 nm or 115 nm, etc. The thickness of the second hole transport layer 416 is 5 nm-20 nm, and the second hole transport layer 416 within such a thickness range may be doped with the P-type material with a higher volume concentration, then the hole transport efficiency can be effectively improved, and the drive voltage of the organic light-emitting diode can be effectively lowered. For example, the thickness of the second hole transport layer 416 may be 8 nm, 10 nm, 12 nm, 14 nm, 15 nm, 16 nm or 18 nm, etc. The setting of specific value may be designed by designers in combination with various elements.

In some embodiments, the volume concentration of the P-type materials of the first hole transport layer 415 is 0.05%˜10%, if the volume concentration of the P-type material is within this range, then it is difficult for the P-type material to permeate into adjacent light emitting layers, and the problem of luminescence quenching is not easily caused, For example, the volume concentration of the P-type material of the first hole transport layer 415 may be 0.1%, 0.15%, 0.18%, 0.2%, 0.5%, 1%, 1.5%, 2.2%, 2.5%, 3%, 3.5%, 4.1%, 4.8%, 5%, 5.5%, 6%, 6.2%, 6.7%, 7%, 7.4%, 7.9%, 8.5%, 9%, 9.5% or 9.7%, etc. The volume concentration of the P-type materials of the second hole transport layer 416 may be 1%˜30%, if the volume concentration of the P-type material is within the range, then more holes may be generated, such that the organic light-emitting diode may be more easily turned on, the drive voltage is lowered, the luminous efficiency is improved, and the service life of the organic light-emitting diode is prolonged. For example, the volume concentration of the P-type material of the second hole transport layer 416 may be 1.5%, 2%, 4%, 4.8%, 5.6%, 6.7%, 8%, 9%, 9.5%, 10%, 12%, 13%, 13.5%, 13.8%, 14.2%, 14.7%, 15%, 16%, 16.5%, 17%, 17.8%, 18%, 20%, 21%, 21.5%, 22%, 22.5%, 23%, 24%, 24.5%, 25%, 25.6%, 26%, 26.5%, 27%, 27.5%, 27.8%, 28%, 28.5%, 29% or 29.7%.

In some embodiments, the thickness of the first electron transport layer 425 is 20 nm˜60 nm, and within this thickness range, the effect of isolating the second electron transport layer 426 with a higher volume concentration of the N-type material from the light emitting layer by the first electron transport layer 425 is favorable. For example, the thickness of the first electron transport layer 425 can be 20.5 nm, 22 nm, 23 nm, 25 nm, 26 nm, 27.5 nm, 28 nm, 29.4 nm, 30 nm, 31 nm, 32 nm, 33.5 nm, 34 nm, 38 nm, 40 nm, 42 nm, 45 nm, 50 nm, 52 nm or 58 nm, etc, The thickness of the second electron transport layer 426 is 5 nm-20 nm, and the second electron transport layer 426 within such a thickness range may be doped with the N-type material with a higher volume concentration, then the electron transport efficiency can be effectively improved, and the drive voltage of the organic light-emitting diode can be effectively lowered. For example, the thickness of the second electron transport layer 426 may be 7 nm, 9 nm, 10 nm, 13.5 nm, 15 nm, 16 nm, 16.5 nm, 17 nm, 18 nm, 19 nm or 19.5 nm, etc. The setting of specific value may be designed by designers in combination with various elements.

In some embodiments, the volume concentration of the N-type material of the first electron transport layer 425 is 0.1%-5%, if the volume concentration of the N-type material is within this range, then it is difficult for the N-type materials to permeate into adjacent light emitting layers, and the problem of luminescence quenching is not easily caused. For example, the volume concentration of the N-type material of the first electron transport layer 425 may be 0.15%, 0.2%, 0.5%, 1%, 1.8%, 2.2%, 2.5%, 3.2%, 3.5%, 4.3% or 4.8%, etc. The volume concentration of the N-type material of the second electron transport layer 426 is 1%-30%, if the volume concentration of the N-type material is within the range, then more electrons may be generated, such that the organic light-emitting diode may be more easily turned on, the drive voltage is lowered, the luminous efficiency of the organic light-emitting diode is improved, and the service life is prolonged. For example, the volume concentration of the N-type material of the second electron transport layer 426 may be 2%, 3%, 4.8%, 6%, 6.7%, 8.5%, 9%, 9.5%, 10%, 13%, 13.5%, 14.2%, 14.7%, 15%, 16.5%, 17.8%, 18%, 20%, 21.5%, 22.5%, 23%, 24.5%, 25%, 26%, 26.5%, 27.5%, 28%, 29% or 29.7%.

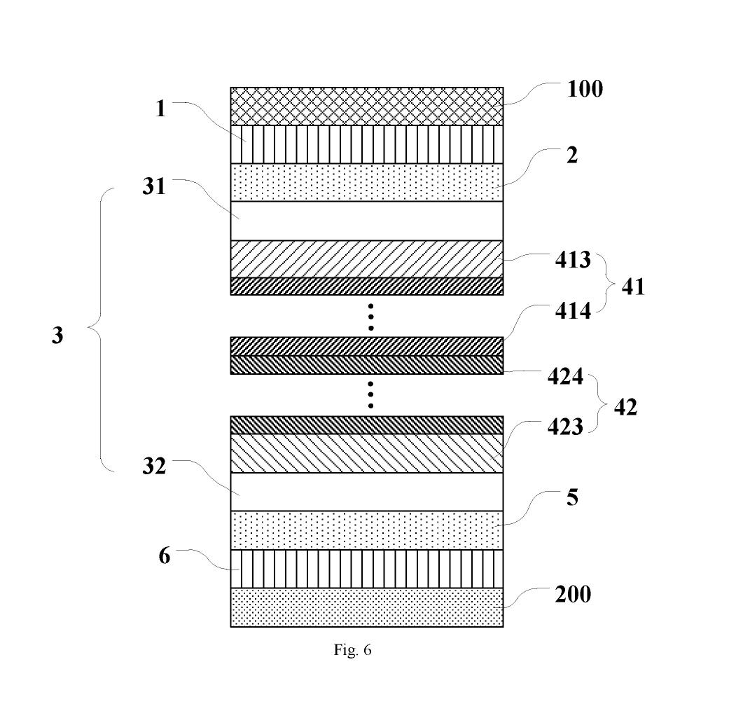

Please refer to FIG. 6. In a fourth embodiment of the present disclosure, the hole transport element 41 includes at least three hole transport layers, which are respectively a third hole transport layer 413 adjacent to the light emitting layer 3 and at least two fourth hole transport layers 414 adjacent to the third hole transport layer 413. The thickness of the third hole transport layer 413 is greater than the thickness of the fourth hole transport layer 414. The volume concentrations of the P-type material of the at least three hole transport layers increase in sequence along the direction far away from the cathode 100. The electron transport element 42 includes at least three electron transport layers, which are respectively a third electron transport layer 423 adjacent to the light emitting layer 3 and the at least two fourth electron transport layers 424 adjacent to the third electron transport layer 423. The thickness of the third electron transport layer 423 is greater than the thickness of the fourth electron transport layer 424; and the volume concentrations of the N-type material of the at least three electron transport layers increase in sequence along the direction far away from the anode 200.

In the present embodiment, the thickness of the third hole transport layer 413 is larger, and the thickness of the third electron transport layer 423 is also larger, therefore, the problem of luminescence quenching is not easily caused. In addition, the volume concentrations of the P-type material of the multiple hole transport layers change gradually, thereby realizing gradient doping of the hole transport layer; and the volume concentrations of the P-type material of the multiple electron transport layers change gradually, thereby realizing gradient doping of the electron transport layer. By adopting this solution, the drive voltage of the organic light-emitting diode can be further lowered, and the luminous efficiency of the organic light-emitting diode can be improved and the service life can be prolonged.

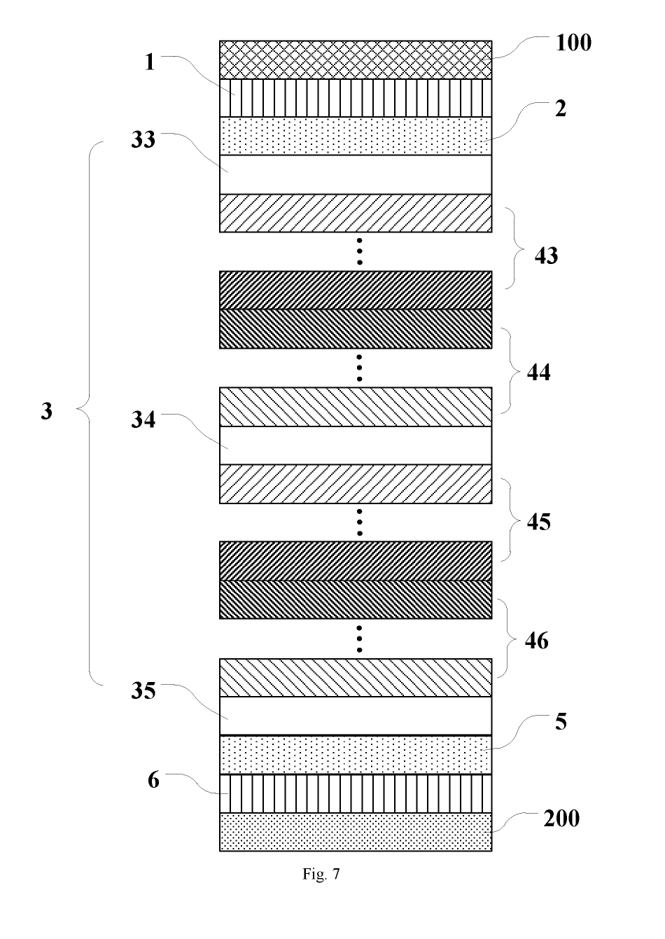

In the above embodiments, the organic light-emitting diode which includes two light emitting layers is taken as an example, in actual application, as shown in FIG. 7. In a fifth embodiment of the present disclosure, the organic light-emitting diode includes three light emitting layers, which are respectively a fifth light emitting layer 33, a sixth light emitting layer 34 and a seventh light emitting layer 35, the hole transport element and the electron transport element in any one of the above technical solutions are both arranged between every two adjacent light emitting layers, which are respectively a first hole transport element 43, a first electron transport element 44, a second hole transport element 45 and a second electron transport element 46, then the drive voltage of the organic light-emitting diode can also be lowered, and the luminous efficiency of the organic light-emitting diode can be improved.

In an optional embodiment, the N-type material includes an alkali metal, an alkaline-earth metal or a rare-earth metal. Illustratively, the metal material includes the combination of any one or at least two of ytterbium, magnesium, lithium, cesium and calcium. The above metal material is doped in the electron transport layer, and may improve the electron transport capability of the electron transport layer.

In some embodiments, the P-type material includes ab inorganic material, and the inorganic materials include MoO₃. The MoO₃ is doped in the hole transport materials as a P-type material, and the hole transport capability of the hole transport layer can be improved.

In an optional embodiment, the P-type material includes an organic material, and the organic material includes:

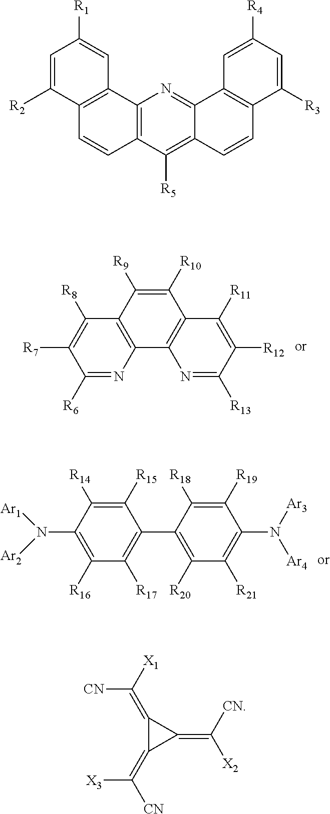

Where R₁ to R₂₁ are independently selected from hydrogen atoms, deuterium atoms, alkyl, alkoxy, substituted or unsubstituted aryl; X₁, X₂ and X₃ are independently selected from substituted or unsubstituted aryl, and the substituent in the substituted or unsubstituted aryl at least includes one electron acceptor group.

Where substituted or unsubstituted aryl exemplarily includes phenyl, tolyl, ethyl phenyl, xylyl, dibiphenylyl, naphthyl, or anthryl, etc.

The above compounds may all improve the hole transport capability of the hole transport layer doped with a P-type material, for example, the compound

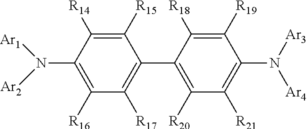

has more conjugated structures, and the its performance is relatively stable, meanwhile, the nitrogen atoms are connected with three conjugated systems, thereby being beneficial for the approach of the electron cloud towards the nitrogen atoms under the electrophilic effect of the nitrogen atoms, and then more holes are formed. Under the effect of large pi bond, the holes may move rapidly, so the compound may play a role of hole transport, and the transport speed of the holes is high. The holes generated by the P-type semiconductor material may transport rapidly in the hole injection materials, then the movement rate of the holes is improved, and the holes may be rapidly combined with the electrons in the light emitting layer to emit light, thereby improving the luminous efficiency of the organic light-emitting diode.

For another example, the compound

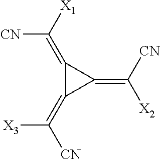

is a radialene compound, and the radialene compound may be used as an organic dopant doped into organic semiconductor to change the electrical property of the semiconductor substrate materials, as a blocker material and a charge injection layer, and as an electrode material. The compound in the embodiment of the present disclosure is connected with an electron acceptor group-CN which has a strong electron withdrawing capability, thereby being beneficial for generating more holes, and improving the hole transport capability of the hole transport layer doped with P-type materials.

In an optional embodiment, the hole transport material includes an aromatic amine material or a carbazole material. The aromatic amine material or carbazole material all have a favorable hole transport performance, and are suitable for being used as hole transport materials.

In an optional embodiment, the electron transport materials includes a biphenyl material, a pyridine material, a benzoylpyridine material or a phenanthroline material. The above materials all have a favorable electron transport performance, and are suitable for being used as electron transport materials.

The embodiment of the present disclosure further provides a display panel, and the display panel includes the organic light-emitting diode in any one of the above technical solutions.

The display panel requires a lower drive voltage, the power consumption is low and the luminous efficiency is high, then the display effect of the display panel is favorable.

The embodiment of the present disclosure further provides a display device, and the display device includes the above display panel.

The display panel included in the display device requires a lower drive voltage, the power consumption is low and the luminous efficiency is higher, then the display effect of the display device can be improved, and the power consumption of the display device is lowered.

Pleaser refer to FIG. 7. The embodiments of the present disclosure further provides a display device 300, and the display device 300 includes a display panel 400 as mentioned above.

The display panel included in the display device requires a lower drive voltage, the power consumption is low and the luminous efficiency is higher, then the display effect of the display device can be improved, and the power consumption of the display device is lowered.

In the embodiments of the present disclosure, the display device is not limited in specific types, and may be a mobile phone, a display, a tablet computer or a television. For example, the display device shown in FIG. 7 is a mobile phone.

Evidently, those skilled in the art can make various modifications and variations to the present disclosure without departing from the scope of the present disclosure. Accordingly, the present disclosure is also intended to encompass these modifications and variations thereto so long as the modifications and variations come into the scope of the claims appended to the present disclosure and their equivalents.

What is claimed is:

1. An organic light-emitting diode, comprising an anode, a cathode, at least two light emitting layers arranged between the anode and the cathode, and a hole transport element and an electron transport element which are arranged between two adjacent light emitting layers and arranged in sequence along a direction far away from the cathode, wherein:
the hole transport element comprises at least two hole transport layers, wherein each of the hole transport layers comprises a hole transport material and a P-type material doped in the hole transport material, and a volume concentration of the P-type material of a hole transport layer adjacent to the light emitting layer is less than a volume concentration of the P-type material of a hole transport layer adjacent to the electron transport element; and
wherein the electron transport element comprises at least two electron transport layers, wherein the electron transport layer comprises an electron transport material and an N-type material doped in the electron transport material, and a volume concentration of the N-type material of an electron transport layer adjacent to the light emitting layer is less than a volume concentration of the N-type material of an electron transport layer adjacent to the hole transport element.

2. The organic light-emitting diode of claim 1, wherein the volume concentrations of the P-type materials of the at least two hole transport layers increase in sequence along the direction far away from the cathode; and
the volume concentrations of the N-type materials of the at least two hole transport layers increase in sequence along a direction far away from the anode.

3. The organic light-emitting diode of claim 1, wherein a thickness of the hole transport layer, adjacent to the light emitting layer, in the at least two hole transport layers is greater than a thickness of remaining hole transport layers; and
a thickness of the electron transport layer, adjacent to the light emitting layer, in the at least two electron transport layers is greater than a thickness of remaining electron transport layers.

4. The organic light-emitting diode of claim 1, wherein the hole transport element comprises two hole transport layers, which are respectively a first hole transport layer and a second hole transport layer along the direction far away from the cathode; and
the electron transport element comprises two electron transport layers, which are respectively a first electron transport layer and a second electron transport layer along a direction far away from the anode.

5. The organic light-emitting diode of claim 4, wherein a thickness of the first hole transport layer is 10 nm˜120 nm, and a thickness of the second hole transport layer is 5 nm˜20 nm.

6. The organic light-emitting diode of claim 4, wherein a volume concentration of the P-type material of the first hole transport layer is 0.05%˜10%, and a volume concentration of the P-type material of the second hole transport layer is 1%˜30%.

7. The organic light-emitting diode of claim 4, wherein a thickness of the first electron transport layer is 20 nm˜60 nm, and a thickness of the second electron transport layer is 5 nm˜20 nm.

8. The organic light-emitting diode of claim 4, wherein a volume concentration of the N-type material of the first electron transport layer is 0.1%˜5%, and a volume concentration of the N-type material of the second electron transport layer is 1%˜30%.

9. The organic light-emitting diode of claim 1, wherein the N-type material comprises an alkali metal, an alkaline-earth metal or a rare-earth metal.

10. The organic light-emitting diode of claim 1, wherein the P-type material comprises an inorganic material, and the inorganic material comprises MoO₃.

11. The organic light-emitting diode of claim 1, wherein the P-type material comprises an organic material, and the organic material comprises: 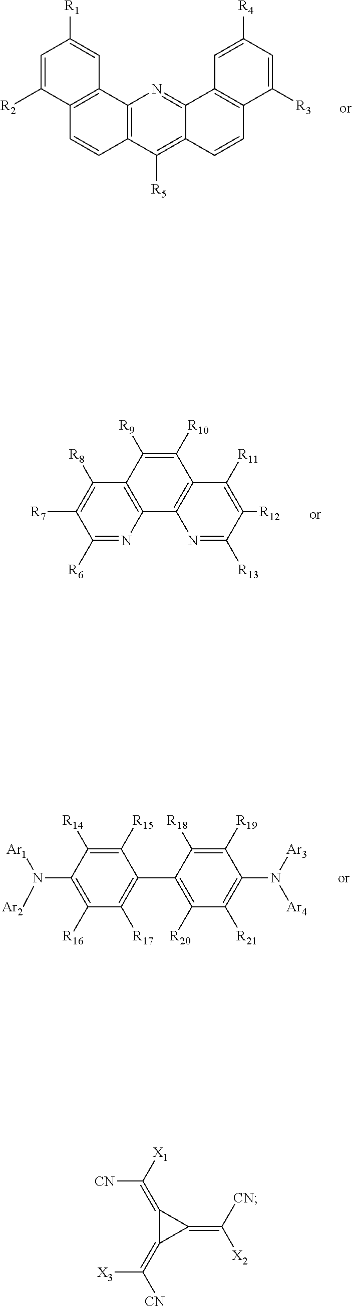
wherein R₁ to R₂₁ are independently selected from hydrogen atoms, deuterium atoms, alkyl, alkoxy, substituted or unsubstituted aryl; X₁, X₂ and X₃ are independently selected from substituted or unsubstituted aryl, and a substituent in the substituted or unsubstituted aryl at least comprises one electron acceptor group.

12. The organic light-emitting diode of claim 1, wherein the hole transport material comprises an aromatic amine material or a carbazole material.

13. The organic light-emitting diode of claim 1, wherein the electron transport material comprises a biphenyl material, a pyridine material, a benzoylpyridine material or a phenanthroline material.

14. A display panel, comprising an organic light-emitting diode, wherein the organic light-emitting diode comprises:
an anode, a cathode, at least two light emitting layers arranged between the anode and the cathode, and a hole transport element and an electron transport element which are arranged between two adjacent light emitting layers and arranged in sequence along a direction far away from the cathode, wherein:
the hole transport element comprises at least two hole transport layers, wherein each of the hole transport layers comprises a hole transport material and a P-type material doped in the hole transport material, and a volume concentration of the P-type material of a hole transport layer adjacent to the light emitting layer is less than a volume concentration of the P-type material of a hole transport layer adjacent to the electron transport element; and
wherein the electron transport element comprises at least two electron transport layers, wherein the electron transport layer comprises an electron transport material and an N-type material doped in the electron transport material, and a volume concentration of the N-type material of an electron transport layer adjacent to the light emitting layer is less than a volume concentration of the N-type material of an electron transport layer adjacent to the hole transport element.

15. A display device, comprising the display panel of claim 14.
